(19) United States
(12) Patent Application Publication
(10) Pub. No.: US 2025/0298074 A1
(43) Pub. Date: Sep. 25, 2025

(54) SYSTEMS, DEVICES, AND METHODS FOR ERROR DETECTION

(71) Applicant: Infineon Technologies AG, Neubiberg (DE)

(72) Inventors: Surya Kiran Venkata Rama Musunuri, Bangalore (IN); Jothish Joseph Kalathil, Ernakulam (IN)

(21) Appl. No.: 19/077,073

(22) Filed: Mar. 12, 2025

(30) Foreign Application Priority Data
Mar. 22, 2024 (DE) 10 2024 108 214.3

(51) Int. Cl. G01R 31/28

(52) U.S. Cl. CPC G01R 31/2884; G01R 31/2882

(57) ABSTRACT

An integrated circuit includes a plurality of electronic devices providing a plurality of functional logic paths and checker logic circuitry. The checker logic circuitry includes a plurality of ring oscillator circuits respectively corresponding to the plurality of functional logic paths, wherein each ring oscillator circuit comprises circuitry in a ring oscillator configuration mirroring its corresponding functional logic path, clock counter circuitry configured to determine frequency values of each of the plurality of ring oscillator circuits; and alarm trigger circuitry. The alarm trigger circuitry is configured to determine whether the determined frequency values cross one or more of a plurality of reference frequency values and trigger one or alarm responses in response to determining one or more of the reference frequency values has been crossed.

### REFERENCE TO RELATED APPLICATION

This application claims priority to German Application number 10 2024 108 214.3, filed on Mar. 22, 2024, the contents of which are hereby incorporated by reference in their entirety.

### TECHNICAL FIELD

Various embodiments generally relate to error detection and integrated circuits with integrated error detection.

### BACKGROUND

Early detection of silicon errors or bugs is important for both the safety and security in integrated circuits (ICs) because these bugs can lead to incorrect or unpredictable behavior. Early detection enables a system to move to a safe state within the Fault Handling Time Interval (FHTI), which can achieve a higher Failures in Time (FIT) rate. However, current post-silicon testing methods suffer from significant latency, with bug detection taking millions of clock cycles. Moreover, these methods are often costly and inadequate in capturing all types of errors, particularly those arising from interactions between different design components. Further, current mechanisms for ICs are designed to trigger an alarm after a failure is detected.

### BRIEF DESCRIPTION OF THE DRAWINGS

In the drawings, like reference characters generally refer to the same parts throughout the different views. The drawings are not necessarily to scale; emphasis instead generally being placed upon illustrating the principles of the invention. In the following description, various embodiments of the invention are described with reference to the following drawings, in which:

FIGS. 1A and 1B each include a diagram illustrating an integrated circuit according to one or more exemplary embodiments of the present disclosure.

FIG. 2 shows a timing path according to at least one exemplary embodiment of the present disclosure.

FIG. 3 includes a table describing a functional logic path according to at least one exemplary embodiment of the present disclosure.

FIG. 4 shows checker logic circuitry according to at least one exemplary embodiment of the present disclosure.

FIG. 5 shows checker logic circuitry according to at least one exemplary embodiment of the present disclosure.

FIG. 6 shows a table including PVTF conditions according to at least one exemplary embodiment of the present disclosure.

FIG. 7 shows an alarm range graph according to at least one exemplary embodiment of the present disclosure.

FIG. 8 shows a state transaction diagram according to at least one exemplary embodiment of the present disclosure.

FIG. 9 shows a flow diagram of a method for error detection according to at least one exemplary embodiment of the present disclosure.

### DESCRIPTION

The following detailed description refers to the accompanying drawings that show, by way of illustration, specific details and embodiments in which the invention may be practiced.

The word “exemplary” is used herein to mean “serving as an example, instance, or illustration.” Any embodiment or design described herein as “exemplary” is not necessarily to be construed as preferred or advantageous over other embodiments or designs.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e., one or more. Any term expressed in the plural form that does not expressly state “plurality” or “multiple” likewise refers to a quantity equal to or greater than one. The terms “proper subset”, “reduced subset”, and “lesser subset” refer to a subset of a set that is not equal to the set, i.e., a subset of a set that contains fewer elements than the set.

The terms “at least one” and “one or more” may be understood to include a numerical quantity greater than or equal to one (e.g., one, two, three, four, [ . . . ], etc.).

As used herein, unless otherwise specified, the use of the ordinal adjectives “first”, “second”, “third”, etc., to describe a common object merely indicate that different instances of like objects are being referred to, and are not intended to imply that the objects so described must be in a given sequence, either temporally, spatially, in ranking, or in any other manner.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in the form of a pointer. However, the term data is not limited to the aforementioned examples and may take various forms and represent any information as understood in the art.

The term “processor” or “controller” as, for example, used herein may be understood as any kind of entity that allows handling data, signals, etc. The data, signals, etc., may be handled according to one or more specific functions executed by the processor or controller.

A processor or a controller may thus be or include an analog circuit, digital circuit, mixed-signal circuit, logic circuit, processor, microprocessor, Central Processing Unit (CPU), Neuromorphic Computer Unit (NCU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

A “circuit” as used herein is understood as any kind of logic-implementing entity, which may include special-purpose hardware or a processor executing software. A circuit may thus be an analog circuit, digital circuit, mixed-signal circuit, logic circuit, processor, microprocessor, signal processor, Central Processing Unit (“CPU”), Graphics Processing Unit (“GPU”), Neuromorphic Computer Unit (NCU), Digital Signal Processor (“DSP”), Field Programmable Gate Array (“FPGA”), integrated circuit, Application Specific Integrated Circuit (“ASIC”), etc., or any combination thereof. Any other kind of implementation of the respective functions, which will be described below in further detail, may also be understood as a “circuit.” It is understood that any two (or more) of the circuits detailed herein may be realized as a single circuit with substantially equivalent functionality. Conversely, any single circuit detailed herein may be realized as two (or more) separate circuits with substantially equivalent functionality. Additionally, references to a “circuit” may refer to two or more circuits that collectively form a single circuit.

As utilized herein, terms “module”, “component,” “system,” “circuit,” “element,” “interface,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

As used herein, a “signal” may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal.

As used herein, a signal that is “indicative of” a value or other information may be a digital or analog signal that encodes or otherwise communicates the value or other information in a manner that can be decoded by and/or cause a responsive action in a component receiving the signal. The signal may be stored or buffered in a computer-readable storage medium prior to its receipt by the receiving component. The receiving component may retrieve the signal from the storage medium. Further, a “value” that is “indicative of” some quantity, state, or parameter may be physically embodied as a digital signal, an analog signal, or stored bits that encode or otherwise communicate the value.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electromagnetic wave in the other element without physical contact or intervening components. Further, when a voltage, current, or signal is referred to as being “applied” to an element, the voltage, current, or signal may be conducted to the element by way of a physical connection or by way of capacitive, electromagnetic, or inductive coupling that does not involve a physical connection.

As used herein, “memory” is understood as a non-transitory computer-readable medium where data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory and thus may refer to a collective component comprising one or more types of memory. Any single memory component may be separated into multiple collectively equivalent memory components and vice versa. Furthermore, while memory may be depicted as separate from one or more other components (such as in the drawings), memory may also be integrated with other components, such as on a common integrated chip or a controller with an embedded memory.

The term “software” refers to any type of executable instruction, including firmware.

Unless specifically stated otherwise, discussions herein using words such as “processing,” “computing,” “calculating,” “determining,” “presenting,” “displaying,” or the like may refer to actions or processes of a machine (e.g., a computer/processor/etc.) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

Exemplary embodiments of the present disclosure may be realized by one or more computers (or computing devices) reading out and executing computer-executable instructions recorded on a storage medium (e.g., non-transitory computer-readable storage medium) to perform the functions of one or more of the herein-described embodiment(s) of the disclosure. The computer(s) may comprise one or more of a central processing unit (CPU), a microprocessor unit (MPU), or other circuitry, and may include a network of separate computers or separate computer processors. The computer-executable instructions may be provided to the computer, for example, from a network or a non-volatile computer-readable storage medium. The storage medium may include, for example, one or more of a hard disk, a random-access memory (RAM), a read-only memory (ROM), a storage of distributed computing systems, an optical drive (such as a compact disc (CD), digital versatile disc (DVD), or Blu-ray Disc (BD), a flash memory device, a memory card, and the like. By way of illustration, specific details and embodiments in which the invention may be practiced.

The term “integrated circuits” as used herein refers to electronic circuits having multiple individual circuit elements, such as transistors, diodes, resistors, capacitors, inductors, and other active and passive semiconductor devices.

Throughout this specification, plural instances may implement components, operations, or structures described as a single instance. Although individual operations of one or more methods are illustrated and described as separate operations, one or more of the individual operations may be performed concurrently. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein

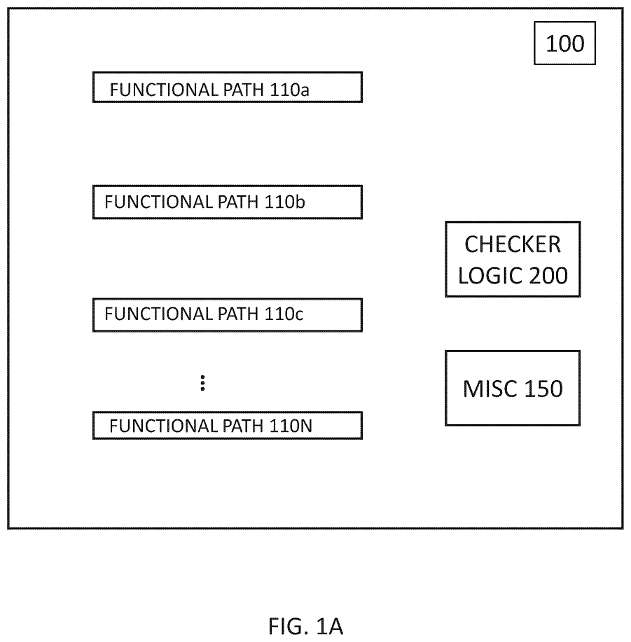

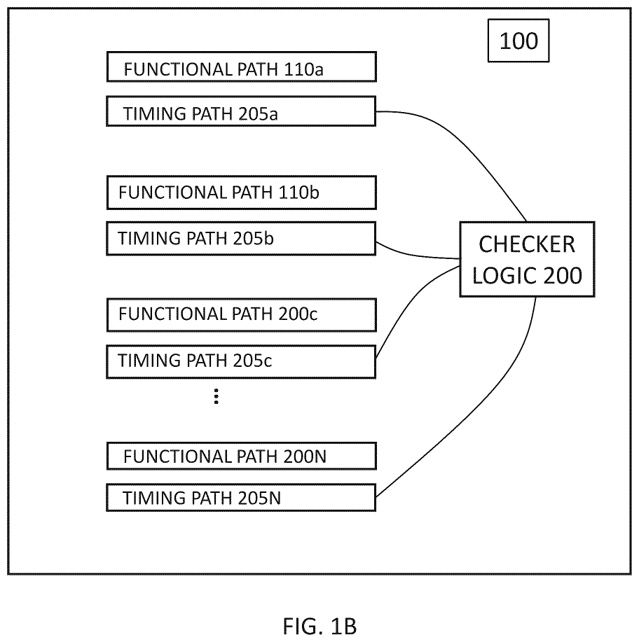

FIG. 1A includes a block diagram illustrating an integrated circuit 100 according to one or more exemplary embodiments of the present disclosure. The integrated circuit (IC) 100 includes, among other things, a plurality of functional paths 110a-110N (also referred collectively of individually as functional path 110). The functional paths 110 may also be called as functional logic paths, logic paths or paths. A functional path 110 can include a plurality of functional components, logic components, cells, sub-components of the IC 100. The functional paths 110 may be connected to other components of the IC 100 which are not depicted in FIG. 1A.

In at least one example, the integrated circuit 100 may be implemented in or as a microcontroller, and as such, may include one or more processor cores as well as other related components. For example, such cores or central processing unit (CPU) cores may perform one or more operations by executing program instructions or software. Such instructions may be stored or located on a (non-transitory) computer readable storage medium located in the microcontroller or IC 100.

In the example of FIG. 1A, the IC 100 may include error detection circuitry configured to detect errors in the circuit. More specifically, the IC 100 can include checker logic circuitry 200 integrated in the IC 100.

The checker logic circuitry 200 can be configured to early pre-detect errors. That is, the checker logic circuitry 200 can be configured to detect pre-alarm conditions or ranges of conditions that occur before actual occurrence of one or more failures in the IC 100. For example, the checker logic circuitry 200 can be configured to monitor certain functional paths of the IC 100, e.g. in real-time, to identify certain deviations, discrepancies, or errors, e.g., before a failure occurs in the IC.

In one or more instances, the checker logic circuitry 200 can be implemented to monitor the N worst or most critical functional paths (e.g., functional paths 110a-110N) of the IC 100. These “worst” or “most critical” functional paths 110 may be identified through any suitable means, e.g., simulation, prior to the fabrication of the IC 100.

As shown in FIG. 1B, which is another depiction of the IC 100, the checker logic circuitry 200 may be implemented to include a plurality of timing paths or paths 205a-205N (also referred to as timing paths 205). Each timing path 205 corresponds to different one of the functional paths 110.

Further, as represented in FIG. 1B, each timing path 205 can implemented to be neighboring or adjacent to its corresponding functional logic path 110. Further, each timing path 205 may connected or coupled to a same input and/or output of its corresponding functional logic path 110. In general, each timing path 205 can be arranged in parallel to its corresponding functional logic path 110. As speed of operation and hence timing can be affected by local conditions for example temperature, arranging the timing path 205 locally to the corresponding functional logic path 110 can reduce influence of temperature differences across the chip.

The timing paths 205 may each be implemented or realized in the form of a ring oscillator circuit, with ring oscillator circuit including circuitry that mirrors its corresponding functional logic path 110. That is, each timing path 205 is designed or configured to mimic or closely mimic its corresponding functional path 110 in terms of behavior, such as, for example, the propagation delay, electrical characteristics, and/or function. By mirroring its corresponding functional logic path, the timing path 205 can have the same or substantially the same cells or components as the functional logic path, which are arranged in the same or substantially manner as the corresponding functional logic path. The only difference can be that the timing path 205 is implemented as a ring oscillator, in which output of the timing path 205 is fed back into the input of the of the timing path. Due to the feedback, each timing path 205, e.g., each ring oscillator circuit, can be designed to satisfy the Barkhausen stability criterion. For example, in some cases, an inversion (e.g., an inverter) may be added to ring oscillator circuit to satisfy the Barkhausen stability criterion.

Further, in at least one example, the timing path/ring oscillator circuits 205 may be each be implemented in hardware or as hardware components. For example, the ring oscillator circuits 205 may be implemented without any software or without the use a processor executing instructions. That is, in one or more examples, the components or cells of the timing path/ring oscillator 205 may be hardwired hardware components. In such cases, the components of the timing path 205 or its settings are not alterable after fabrication in the IC 100.

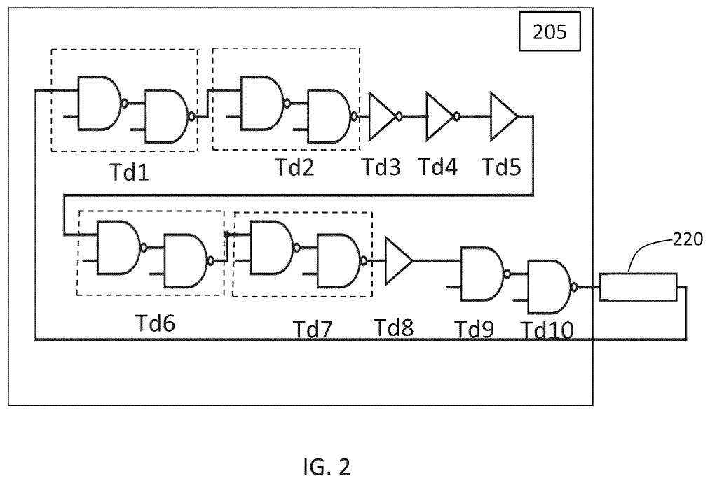

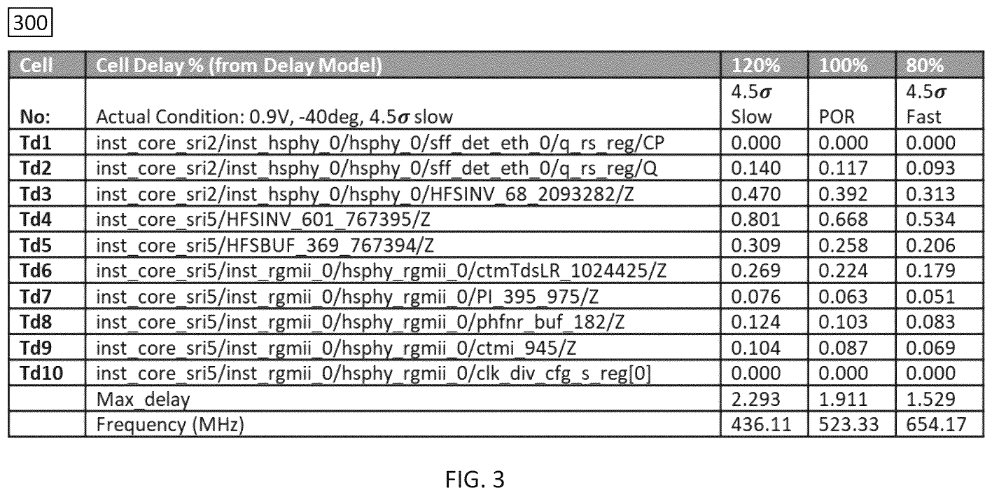

FIG. 2 shows one example of a timing path 205. FIG. 3 includes a table 300 describing a functional logic path to which the timing path of FIG. 2 corresponds. The table 300 includes entries of the cells or functional components of the functional logic path. For each cell there is entries including description of characteristics or properties of each cell or component.

The timing path 205 is arranged as a ring oscillator circuit that includes components Td1-Td10 and hence mirrors the components or cells (also labeled Td1-Td10) of the functional logic path described in table 300. Since the timing path is designed or configured to mimic or mirror the functional logic path described in table 300, the components Td1-Td10 are therefore arranged in the same order or sequence as the functional logic path described in table 300. Further, the output of the last cell/component, Td10, is coupled to the input of the first cell/component Td1. Accordingly, the timing path 205 and other timing paths described herein, can have the same or substantially same prorogation or path delay as its corresponding functional logic path. For example, timing paths described herein such as the timing path 205 of FIG. 2 may have a path delay within 5% of its corresponding functional path.

Note that the circuitry around the timing path 205 need not be the same as that around its corresponding functional path 110 and at least some of the components Td1-Td10 on the timing path 205 may have gates connected preselected, controllable or constant voltage inputs. For example, referring to FIG. 2, the lower gate inputs in first cell Td1, which are not connected to the ring or other components Td2-Td10 of the timing path, may be connected to constant values, while the corresponding gates in functional path 110 may be connected to varying inputs. The components Td1-Td10 of the timing path 205 should at least substantially mirror the timing of the components of the functional path 110 but need not necessarily produce the same output.

FIG. 2 shows that the output from the ring oscillator circuit 205 is also coupled to a clock counter circuitry 220. The clock counter circuitry or frequency counter 220 is configured to count or determine a frequency of the timing path 205 based on its output. The frequency or frequency values determined by the clock counter circuitry 220 can be used as described herein.

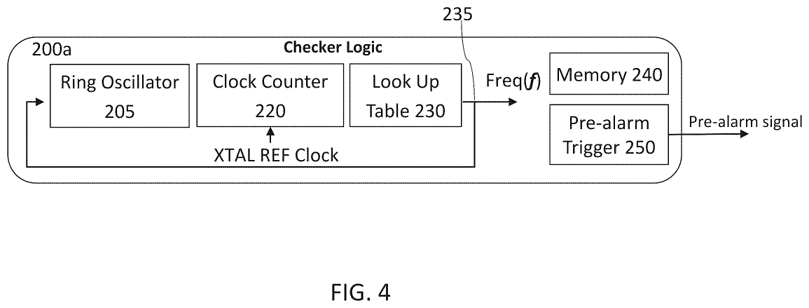

FIG. 4 shows one example of the checker logic circuitry 200 shown in FIGS. 1A and 1B. In the example of the FIG. 4, the checker logic circuitry 200a includes at least one timing path or ring oscillator circuit 205. Although only a single individual ring oscillator circuit 205 is depicted, this is merely to simply explanation of the checker logic circuitry. The checker logic circuitry 200a can include any suitable number of timing paths or ring oscillator circuits 205.

As shown in FIG. 4, the checker logic circuitry 200a further includes a clock counter circuitry 220. The clock counter circuitry 220 determines or ascertains the current frequency or frequency value of each of the one or more ring oscillator circuits 205, e.g., repeatedly, or continuously. The clock counter circuitry 220, e.g., a frequency counter, is configured to receive a clock signal for determining the frequency of each of the one or more timing paths 205. This clock signal may be received from a source or component that is arranged external to the checker logic circuitry 200. In some instances, the clock signal may be generated from a source that is external to the IC 100. The clock signal, e.g., XTAL Ref., may be generated from a crystal oscillator circuit, which may be part of the IC 100.

In FIG. 4, the checker logic circuitry 200a includes a pre-alarm trigger circuitry 250. The pre-alarm trigger circuitry 250 can compare the output frequencies or frequency values from the clock counter with one or more reference frequencies or frequency values. The one or more reference frequency values can be used as thresholds. In particular, the one or more reference frequency values can be either upper or lower thresholds.

The pre-alarm trigger circuitry 250 compares the output frequency values from each of the ring oscillator circuits 205 to the one or more reference or threshold frequencies. Specifically, the pre-alarm trigger circuitry 250 determines whether the output frequency values cross the reference frequency values. That is, the pre-alarm trigger circuitry 250 determine if the output frequency values exceed or fall below the reference frequency values. For example, ‘crossing’ a reference frequency value refers to the scenario where an output frequency either drops below a reference frequency value, which acts as a lower threshold, or surpasses a reference frequency value which acts as an upper threshold. Said differently, the pre-alarm trigger circuitry 250 determines whether an output frequency or output frequency values fall below reference frequency values that act as a lower threshold and/or determine whether output frequency values exceed reference frequency values that act or serve as an upper threshold.

When the frequency values from the ring oscillator circuit(s) are determined by the pre-alarm trigger circuitry 250 to cross one or more reference frequency values, the pre-alarm trigger circuitry 250 is configured to generate an alarm response. In one or more examples, the alarm response can include generating or outputting one or more alarm interrupts or alarm signals. For instance, the alarm signals can be considered pre-alarm signals that indicate one or more potential issues or problems in the IC 100, e.g., before occurrence of an actual failure. Further, the pre-alarm trigger circuitry 250 can be configured to output an alarm or pre-alarm interrupt(s) that cause the IC 100 or one or more parts thereof (e.g., one or more functional logic paths) to enter another state. For example, the IC 100 may enter a safe state, a pre-alarm state, or an alarm state.

The pre-alarm trigger circuitry 250 may include, for example, comparator circuits or comparator circuitry for comparing frequencies from the clock counter 220 with the reference or threshold frequency values. These reference frequency values may be stored in a look-up table (LUT) 230. In some instances, the LUT 230 may be part of the checker logic circuitry 200a, but this is not necessarily so as it can be included in other sections of the IC 100, or in a component external to the IC 100.

In one or more exemplary embodiments of the present disclosure, each of the plurality of reference frequency values corresponds to a combination of IC or circuit conditions. The conditions that may be a combination that can include, for instance, a process condition, a voltage condition, a temperature condition, and/or a frequency variation condition. A combination such conditions of may be referred to as a PVTF condition.

A crossing of a reference frequency value boundary can indicate that a functional path is deviating outside a range of its normal or nominal operating conditions, e.g., with respect to one or more or conditions (e.g., voltage, temperature, etc.). That is, a determined frequency value(s) of a ring oscillator crossing a reference frequency value can indicate that the corresponding functional path is operating close or unacceptably close to failure. Conversely, when the determined frequency values do not cross the reference frequency values, this can be indicative that the corresponding functional path is operating within normal or nominative operating conditions.

Referring back to FIG. 4, the checker logic circuitry 200a may include a memory circuit or component 240 (e.g. registers) that store PVTF conditions. For example, the memory 240 can store data of PVTF conditions that are considered in a pre-alarm range or failed range. The IC 100 can use these stored PVTF conditions, e.g., the values indicated for the PVTF conditions, to generate reference frequency values and then can store the reference frequency values in the LUT 230. As mentioned, each reference frequency value can correspond to a PVTF condition to be checked or monitored. A processing device or other circuitry of the IC 100 can be used to generate the reference frequency values using the PVTF condition values stored in the memory 240. In other cases, the reference frequency values may be provided or set from a source external to the IC 100. The PVTF conditions or its values can be configurable, e.g., user configurable. In response to a change to the stored PVTF conditions, the IC 100 can be configured to update or regenerate corresponding reference frequency values and store them in the LUT 230.

While the checker logic circuitry 200a depicted FIG. 4 is shown for identifying deviations and pre-alarm conditions situations for a single functional logic path 110, it can easily be extended or implemented for a plurality of functional paths. Each of a plurality of functional paths 110 can be monitored for potential errors and deviations. To accomplish this, the checker logic circuitry 200a can provide a corresponding a timing path or ring oscillator circuit 205 for each the plurality of functional paths. Other components described in the checker logic circuitry 200a, namely the clock counter 220, LUT 230, memory 240, and pre-alarm trigger circuitry 250 may also be provided for each functional logic path 110. In other cases, the clock counter 220, LUT 230, memory 240, and/or the pre-alarm circuitry may be shared and applied to one or more functional paths 110/ring oscillators 205. In any event, in the context of FIG. 4, the checker logic circuitry 200a can provide one or more pre-alarm signal responses, e.g., pre-alarm signals independently for each functional path 110 being monitored.

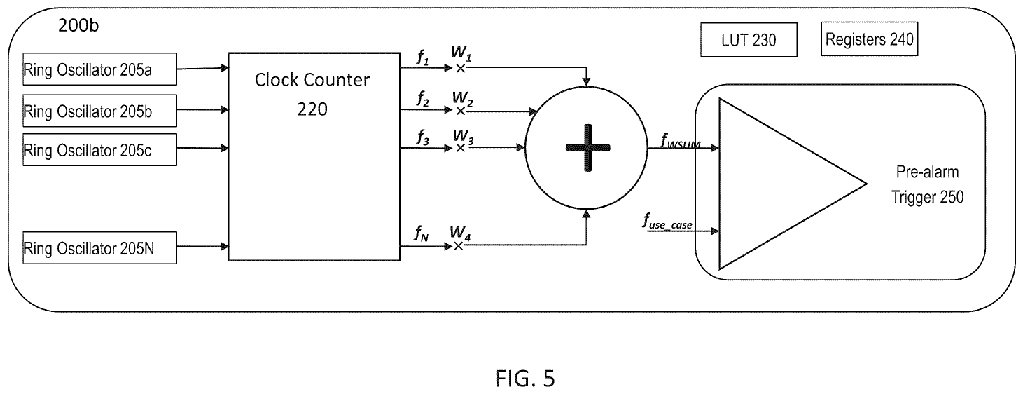

FIG. 5 shows another example of checker logic circuitry described in FIG. 1B. In FIG. 5, the checker logic circuitry 200b is similar to the checker logic circuitry 200a in that it includes a plurality of timing paths 205a-205N (timing paths 205). Again, each of these timing paths 205 may each be implemented as a ring oscillator that is implemented with components to mimic a corresponding functional logic path of the IC 100 as described previously. As previously described, a clock counter circuit or frequency counter 220 can determine the frequency values for each of the ring oscillator circuits 205.

However, in the example of FIG. 5, checker logic circuitry 200b does not individually or separately compare the frequency values from ring oscillator circuits (f₁-fₙ) to reference frequency values (e.g., stored in the LUT 230) for determining deviations in the functional logic paths 110 and generating (pre-) alarm responses.

Instead, the checker logic circuitry 200b uses a combination the frequency values of the ring oscillator circuits 205. In other words, the checker logic circuitry 200b generates or determine weighted sums of frequency values (fₛᵤₘ) from the ring oscillator circuits 205. A weighted sum can be defined or expressed as follows:

$${f}_{sum} = {W}_{1} {f}_{1} + {W}_{2} {f}_{1} + ⋯ {W}_{N} {f}_{N}$$

The weighted sum, fₛᵤₘ, can be compared against one or more threshold or reference frequency values by the pre-alarm trigger circuitry 250. Again, as described in connection with the checker logic circuitry 200a of FIG. 4, each reference frequency value can correspond to a PVTF condition being monitored or checked. Like the checker logic circuitry 200a, the pre-alarm circuitry 250 of checker logic circuitry 200b can generate a pre-alarm response(s), e.g., output a pre-alarm signal(s), in response to a weighted sum crossing a reference or threshold frequency value. That is, if a weighted sum fₛᵤₘ exceeds a reference frequency value that serves as an upper threshold and/or if the weighted sum fₛᵤₘ falls below a reference values that serves as a lower threshold, the pre-alarm circuitry can generate a pre-alarm response. Again, the pre-alarm circuitry 250 of FIG. 5 may include comparator circuit(s) or comparator circuitry to compare the determined weighted sums from the plurality of ring oscillator circuits 205 against one or more reference frequency values.

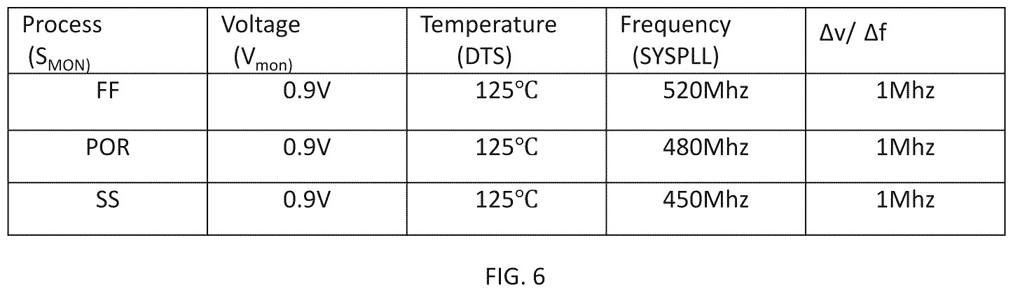

FIG. 6 shows a table 600 below shows an example of PVTF conditions to be used for evaluating timing paths by checker logic circuitry herein. The table 600 shows example of data or information that may be stored in IC 100, e.g., in the memory/registers 240. In the example of FIG. 6, each row entry indicates a specific conditions to be monitored and its relation to a determined failure boundary (Δv/Δf). From such data, one or more reference or threshold frequency values can be determined or calculated.

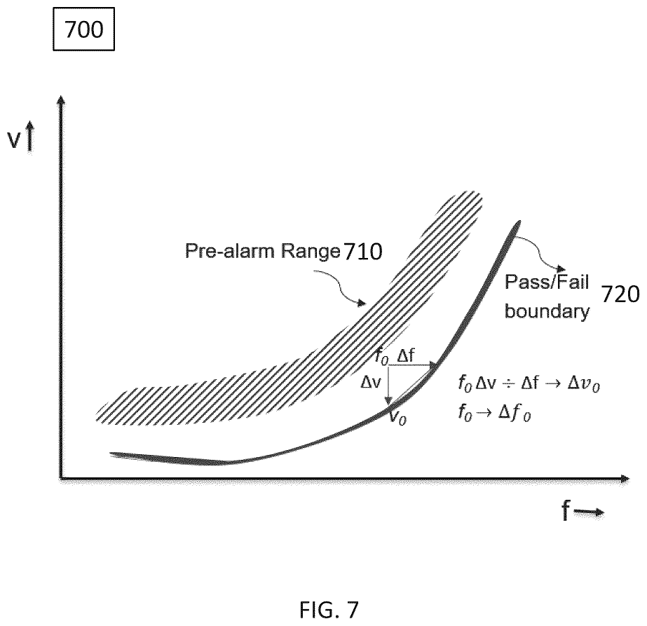

FIG. 7 shows a graph 700 showing plotted exemplary pre-alarm and fail boundaries. Namely, the frequency, f, along the x-axis can correspond to a frequency value produced from checker logic circuitries described herein, e.g., from a timing path or ring oscillator circuit or from a weighted sum of frequencies from timing paths. The pre-alarm range 710 can indicate for certain voltage values, the frequencies at which a pre-alarm state or pre-alarm response should be generated or provided.

In the graph 170, the pass/fail or failure boundary 720 indicate where or when the integrated circuit or functional path is expected to fail given the voltage or frequency values produced, e.g., by the functional path. These reference frequency values that define the pre-alarm range 710 and the pass-fail boundary 720 may be determined or identified through silicon testing of an IC (e.g., IC 100), or through simulation of the IC.

For example, generating or obtaining reference or threshold frequency values can include developing one or more tests to trigger the identified path (e.g., functional logic path), the test(s) across various PVTF. Then after applying such tests and collecting data therefrom, a model is developed. Then the model can be used to generate or predict a pre-alarm range, for example a voltage and frequency relation with respect to a failure boundary or for other PVTF scenarios. The model can be used by the IC 100 to generate reference frequency values for certain specified PVTF conditions.

While the graph 700 only shows frequency versus voltage in a 2D plot, in other cases, the graph can be extended to multiple dimensions, e.g., 3D with other parameters, such as temperature, process, etc.

In accordance with one or more embodiments herein, trigger alarm circuitries described herein may generate a pre-alarm response. The pre-alarm response may include generating one or more (pre-) alarm signals or (pre-) alarm interrupts that can cause one or more functional logic paths, or aspects of the IC 100 to enter a pre-alarm state or an alarm state.

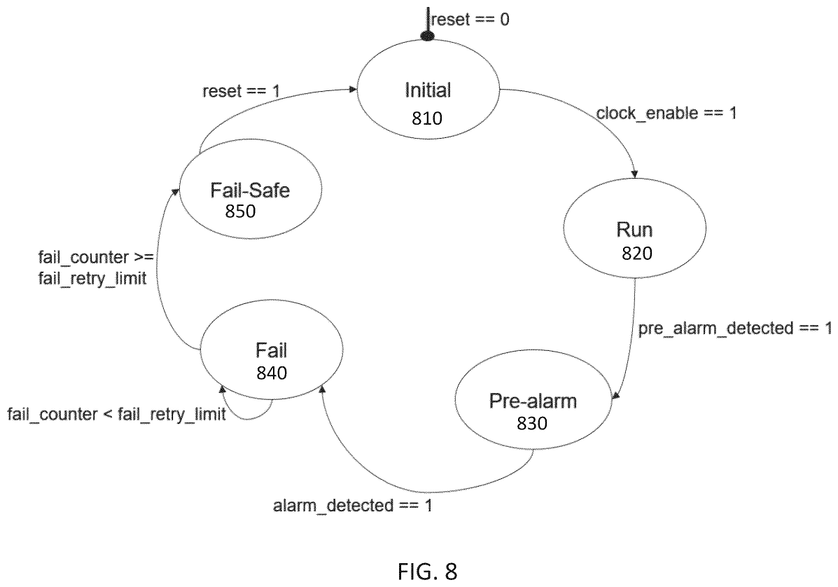

FIG. 8 shows one example of a state transaction diagram for the IC 100. That is, the IC 100, or more specifically or its functional logic paths may operate in multiple states. For example, the IC 100 may operate or exist in an Initial state 810. This may be a default state for configuring or defining thresholds and pre-alarms. The IC 100 can transition to the Run state 820, where the IC 100 or its functional logic paths can operate normally within the passing frequency range.

The IC 100 can transition from the Run state 820 to a Pre-alarm state 830. The IC 100 can transition into the Pre-alarm state 830 in response to Pre-alarms being are triggered (e.g., by comparing frequency values obtained from the ring oscillators with the threshold or reference frequency values). In the Pre-alarm state 830, and values of the IC 100, e.g., marginal values are stored before an actual failure occurs.

The IC 100 can further transition to a Fail state 840. The IC 100 can enter the Fail state 840 upon the occurrence of a conventional failure, e.g., frequency range with safety alarms triggered.

Further, the IC 100 can enter a Fail-safe state 850 when experienced failures exceed a threshold limit. The IC 100 can enter and remain in the Fail-safe state 850 until a reset of the IC 100.

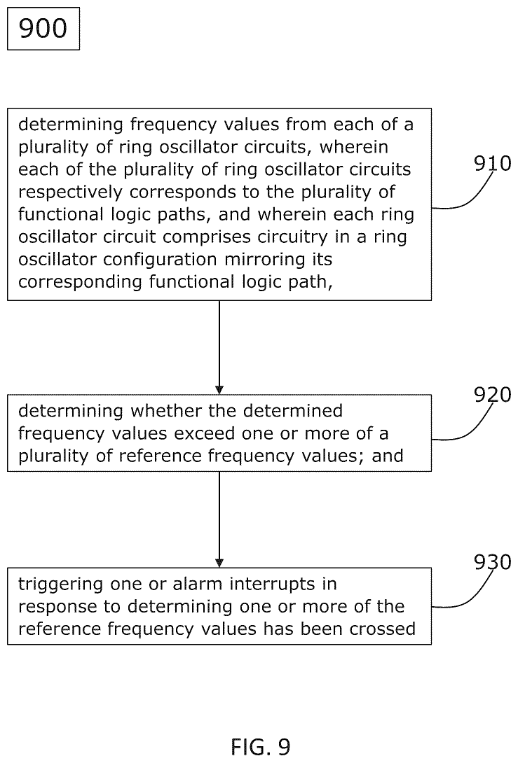

FIG. 9 shows a method 900 for error detection. The method 900 can be implemented on or using an integrated circuit including a plurality of electronic devices providing a plurality of functional logic paths. For example, the ICs described herein, e.g., IC 100, can implement the method 900,

The method 900 includes, at 910, determining frequency values from each of a plurality of ring oscillator circuits, wherein each of the plurality of ring oscillator circuits respectively corresponds to the plurality of functional logic paths, and wherein each ring oscillator circuit comprises circuitry in a ring oscillator configuration mirroring its corresponding functional logic path. At 920, the method 900 includes determining whether the determined frequency values exceed one or more of a plurality of reference frequency values. At 930, the method includes triggering an alarm response in response to determining one or more of the reference frequency values has been exceeded.

ICs described herein can include checker logic circuitry that can provide bug/error detection which allows for proactive bug resolution, optimizing system performance, and improving product quality. Identifying potential bugs or errors and areas of concern enables timely adjustments by design teams. Further, the checker logic circuities described herein can operate in real-time. Said differently, the checker logic circuitries can monitor functional components in real-time, swiftly identifying deviations, discrepancies, or errors. It can perform or cause the performance of corrective or preventive actions to address bugs before they lead to significant issues.

Further, the ICs and checker logic circuitries described herein may be customized to meet specific design requirements, incorporating application-specific checks for comprehensive bug detection. It seamlessly integrates with existing designs, requiring minimal modifications, and ensuring compatibility across various use cases.

The following examples pertain to further aspects of this disclosure:

Example 1 is an integrated circuit including: a plurality of electronic devices providing a plurality of functional logic paths; checker logic circuitry including a plurality of ring oscillator circuits respectively corresponding to the plurality of functional logic paths, wherein each ring oscillator circuit comprises circuitry in a ring oscillator configuration mirroring its corresponding functional logic path, clock counter circuitry configured to determine frequency values of each of the plurality of ring oscillator circuits; alarm trigger circuitry configured to determine whether the determined frequency values cross one or more of a plurality of reference frequency values, and trigger one or alarm responses in response to determining one or more of the reference frequency values has been crossed.

Example 2 is the subject matter of Example 1, wherein one or more of the plurality of reference frequency values can indicate a lower threshold, and wherein to determine whether the determined frequency values cross one or more of a plurality of reference frequency values can include to determine whether the determined frequency values are lower than the one or more of the plurality of reference frequency values indicating a lower threshold.

Example 3 is the subject matter of Example 1 or 2, wherein one or more of the plurality of reference frequency values can indicate an upper threshold, and wherein to determine whether the determined frequency values cross one or more of a plurality of reference frequency values can include to determine whether the determined frequency values are higher than the one or more of the plurality of reference frequency values indicating an upper threshold.

Example 4 is the subject matter of any of Examples 1 to 3, wherein the circuitry each of the plurality of ring oscillator circuits can be arranged in parallel between an input and an output of its respective corresponding functional logic path.

Example 5 is the subject matter of any of Examples 1 to 4, wherein the circuitry of each of the plurality of ring oscillator circuits can mirror its respective corresponding functional logic path so as to realize a substantially same path delay as a path delay of the respective functional logic path.

Example 6 is the subject matter of any of Examples 1 to 5, wherein each of the plurality of ring oscillator circuits can be arranged in the integrated circuit adjacent or neighboring to its corresponding functional logic path.

Example 7 is the subject matter of any of Examples 1 to 6, wherein the circuitry of each of the plurality of ring oscillator circuits can include hardwired hardware circuitry.

Example 8 is the subject matter of Example 7, wherein the circuitry of each of the plurality of ring oscillator circuits can operate without software involvement.

Example 9 is the subject matter of any of claims 1 to 8, wherein each of the plurality of reference frequency values can correspond to a combination of conditions one of a process, voltage, temperature, and/or frequency variation (PVTF) condition.

Example 10 is the subject matter of any of Examples 1 to 9, wherein the checker logic circuitry can include a look-up table including the plurality of reference frequency values.

Example 11 is the subject matter of Example 10, which may further include a memory circuit storing a plurality of PVTF conditions, wherein the integrated circuit can be configured to generate the plurality of reference frequency values for the look up table using the plurality of PVTF conditions.

Example 12 is the subject matter of Example 11, wherein the plurality of PVTF conditions can be user-configurable.

Example 13 is the subject matter of any of Examples 1 to 12, wherein the alarm trigger circuitry can be configured to determine one or more weighted sums of the determined frequency values from the plurality of ring oscillator circuits, and wherein to compare the determined frequency values of the plurality of ring oscillator circuits to the one or more reference frequency values can include to compare the one or more weighted sums to the one or more reference frequency values.

Example 14 is the subject matter of any of Examples 1 to 13, wherein to compare the determined frequency values of the plurality of ring oscillator circuits to the one or more reference frequency values can include to individually compare one or more of the determined frequency values to one or more of the plurality of reference frequency values.

Example 15 is the subject matter of any of Examples 1 to 14, wherein the alarm trigger circuitry can include comparator circuitry to compare the determined frequency values of the plurality of ring oscillator circuits to the one or more reference frequency values.

Example 16 is the subject matter of any of Examples 1 to 15, wherein to trigger one or alarm responses in response to determining one or more of the reference frequency values has been crossed can include to output one or more alarm signals.

Example 17 is the subject matter of any of Examples 1 to 16, wherein to trigger one or alarm responses in response to determining one or more of the reference frequency values has been crossed can include to trigger or generate one or more alarm interrupts.

Example 18 is the subject matter of any of Examples 1 to 17, wherein to trigger one or alarm responses in response to determining one or more of the reference frequency values has been crossed can include to cause one or more electronic components of the integrated circuit to enter a pre-alarm state and store one or more current values of the one or more electronic components.

Example 19 is the subject matter of any of Examples 1 to 18, wherein the checker logic circuitry can be configured to trigger the one or more alarm responses in real-time.

Example 20 is the subject matter of any of Examples 1 to 19, wherein the checker logic circuitry can be configured to trigger the one or more alarm response prior to a failure associated with the alarm response occurs.

Example 21 is the subject matter of any of Examples 1 to 20, wherein the plurality of functional logic paths can include one or more electronic components.

Example 1A is a method for integrated circuit including a plurality of electronic devices providing a plurality of functional logic paths, the method including: determining frequency values from each of a plurality of ring oscillator circuits, wherein each of the plurality of ring oscillator circuits respectively corresponds to the plurality of functional logic paths, and wherein each ring oscillator circuit comprises circuitry in a ring oscillator configuration mirroring its corresponding functional logic path; determining whether the determined frequency values cross one or more of a plurality of reference frequency values; and triggering an alarm response in response to determining one or more of the reference frequency values has been crossed.

Example 2A is the subject matter of Example 1A, wherein one or more of the plurality of reference frequency values can indicate a lower threshold, and wherein determining whether the determined frequency values cross one or more of a plurality of reference frequency values can include determining whether the determined frequency values are lower than the one or more of the plurality of reference frequency values indicating a lower threshold.

Example 3A is the subject matter of Example 1A or 2A, wherein one or more of the plurality of reference frequency values cam indicate an upper threshold, and wherein determining whether the determined frequency values cross one or more of a plurality of reference frequency values can include determining whether the determined frequency values are higher than the one or more of the plurality of reference frequency values indicating an upper threshold.

Example 4A is the subject matter of any of Examples 1A to 3A, wherein determining frequency values from each of a plurality of ring oscillator circuits can include using a clock counter circuitry to determine frequency values of each of the plurality of ring oscillator circuits.

Example 5A is the subject matter of any of Examples 1A to 4A, wherein the circuitry each of the plurality of ring oscillator circuits can be arranged in parallel between an input and an output of its respective corresponding functional logic path.

Example 6A is the subject matter of Example 5A, wherein the circuitry of each of the plurality of ring oscillator circuits can be configured to mirror its respective corresponding functional logic path so as to realize a same or substantially same path delay as a path delay of the respective functional logic path.

Example 7A is the subject matter of any of Examples 1A to 6A, wherein the circuitry of each of the plurality of ring oscillator circuits can include hardwired hardware circuitry.

Example 8A is the subject matter of Example 7A, wherein the circuitry of each of the plurality of ring oscillator circuits can operate without software involvement.

Example 9A is the subject matter of any of Examples 1A to 8A, wherein each of the plurality of reference frequency values can correspond to one of a process, voltage, temperature, or frequency variation (PVTF) condition.

Example 10A is the subject matter of Example 9A, wherein the integrated circuit can include a look-up table including the plurality of reference frequency values, and can further include generating the plurality of reference frequency values for the look up table using the plurality of PVTF conditions.

Example 11A is the subject matter of Example 10A, which may further include obtaining, from an input source, the plurality of PVTF conditions are user-configurable; and storing the plurality of PVTF conditions in a memory circuit.

Example 12A is the subject matter of any of Examples 1A to 11A, which can further include: determining one or more weighted sums using the determined frequency values, and wherein comparing the determined frequency values of the plurality of ring oscillator circuits to the one or more reference frequency values can include comparing the one or more determined weighted sums to the one or more reference frequency values.

Example 13A is the subject matter of any of Examples 1A to 12A, wherein comparing the determined frequency values of the plurality of ring oscillator circuits to the one or more reference frequency values can include to individually comparing one or more of the determined frequency values to one or more of the plurality of reference frequency values.

Example 14A is the subject matter of any of Examples 1A to 13A, wherein triggering one or alarm responses in response to determining one or more of the reference frequency values has been crossed can include outputting one or more alarm signals.

Example 15A is the subject matter of any of Examples 1A to 14A, wherein triggering one or alarm responses in response to determining one or more of the reference frequency values has been crossed can include: causing one or more electronic components of the integrated circuit to enter a pre-alarm state, and storing in a non-volatile memory one or more current values of the one or more electronic components.

Example 16A is the subject matter of any of Examples 1A to 15A, wherein the plurality of functional logic paths can include one or more electronic components.

Example 17A is the subject matter of any of Examples 1A to 15A, wherein triggering an alarm response can include generating one or more alarm interrupts or alarm signals.

It should be noted that one or more of the features of any of the examples above may be suitably or appropriately combined with any one of the other examples or with embodiments disclosed herein.

The foregoing description has been given by way of example only and it will be appreciated by those skilled in the art that modifications may be made without departing from the broader spirit or scope of the invention as set forth in the claims. The specification and drawings are therefore to be regarded in an illustrative sense rather than a restrictive sense.

The scope of the disclosure is thus indicated by the appended claims and all changes which come within the meaning and range of equivalency of the claims are therefore intended to be embraced.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An integrated circuit comprising:
a plurality of electronic devices providing a plurality of functional logic paths;
checker logic circuitry comprising:
a plurality of ring oscillator circuits respectively corresponding to the plurality of functional logic paths, wherein each ring oscillator circuit comprises circuitry in a ring oscillator configuration mirroring its corresponding functional logic path,
clock counter circuitry configured to determine frequency values of each of the plurality of ring oscillator circuits; and
pre-alarm trigger circuitry configured to:
determine whether the determined frequency values cross one or more of a plurality of reference frequency values, and
trigger one or more alarm responses in response to determining one or more of the reference frequency values has been crossed.

2. The integrated circuit of claim 1,
wherein one or more of the plurality of reference frequency values indicates a lower threshold or an upper threshold, and
when the one or more of the plurality of reference frequency values indicates a lower threshold, the determining whether the determined frequency values cross one or more of a plurality of reference frequency values comprises to determine whether the determined frequency values are lower than the one or more of the plurality of reference frequency values indicating a lower threshold, and
when the one or more of the plurality of reference frequency values indicates an upper threshold, the determining whether the determined frequency values cross one or more of a plurality of reference frequency values comprises to determine whether the determined frequency values are higher than the one or more of the plurality of reference frequency values indicating an upper threshold.

3. The integrated circuit of claim 1,
wherein the circuitry each of the plurality of ring oscillator circuits is arranged in parallel between an input and an output of its respective corresponding functional logic path.

4. The integrated circuit of claim 1,
wherein the circuitry of each of the plurality of ring oscillator circuits is designed to mirror its respective corresponding functional logic path so as to realize a substantially same path delay as a path delay of the respective functional logic path.

5. The integrated circuit of claim 1,
wherein each of the plurality of ring oscillator circuits is arranged in the integrated circuit adjacent to its corresponding functional logic path.

6. The integrated circuit of claim 1,
wherein the circuitry of each of the plurality of ring oscillator circuits comprises hardwired hardware circuitry or without software involvement.

7. The integrated circuit of claim 1,
wherein each of the plurality of reference frequency values corresponds to a combination of conditions one of a process, voltage, temperature, and/or frequency variation (PVTF) condition.

8. The integrated circuit of claim 1,
wherein the checker logic circuitry comprises a look-up table including the plurality of reference frequency values.

9. The integrated circuit claim 8, further comprising:
a memory circuit storing a plurality of PVTF conditions, and
wherein the integrated circuit is configured to generate the plurality of reference frequency values for the look up table using the plurality of PVTF conditions.

10. The integrated circuit of claim 9,
wherein the plurality of PVTF conditions are user-configurable.

11. The integrated circuit of claim 1,
wherein the pre-alarm trigger circuitry is configured to determine one or more weighted sums of the determined frequency values from the plurality of ring oscillator circuits, and
wherein to compare the determined frequency values of the plurality of ring oscillator circuits to the plurality of reference frequency values comprises to compare the one or more weighted sums to the plurality of reference frequency values.

12. The integrated circuit of claim 1,
wherein to compare the determined frequency values of the plurality of ring oscillator circuits to the plurality of reference frequency values comprises to individually compare one or more of the determined frequency values to the plurality of reference frequency values.

13. The integrated circuit of claim 1,
wherein the pre-alarm trigger circuitry comprises comparator circuitry to compare the determined frequency values of the plurality of ring oscillator circuits to the plurality of reference frequency values.

14. The integrated circuit of claim 1,
wherein to trigger one or more alarm responses in response to determining one or more of the reference frequency values has been crossed comprises to output one or more alarm signals.

15. The integrated circuit of claim 1,
wherein to trigger one or more alarm responses in response to determining one or more of the reference frequency values has been crossed comprises to trigger one or more alarm interrupts.

16. The integrated circuit of claim 1,
wherein to trigger one or more alarm responses in response to determining one or more of the reference frequency values has been crossed comprises to cause one or more electronic components of the integrated circuit to enter a pre-alarm state and store one or more current values of the one or more electronic components.

17. The integrated circuit of claim 1,
wherein the checker logic circuitry is configured to trigger the one or more alarm responses in real-time, and
wherein the checker logic circuitry is configured to trigger the one or more alarm responses prior to occurrence of a failure associated with the one or more alarm responses.

18. A method for integrated circuit including a plurality of electronic devices that provide a plurality of functional logic paths, the method comprising:
determining frequency values from each of a plurality of ring oscillator circuits, wherein each of the plurality of ring oscillator circuits respectively corresponds to the plurality of functional logic paths, and wherein each ring oscillator circuit comprises circuitry in a ring oscillator configuration mirroring its corresponding functional logic path,
determining whether the determined frequency values cross one or more of a plurality of reference frequency values; and
triggering an alarm response in response to determining that one or more of the reference frequency values has been crossed.

19. Checker logic circuitry, comprising:
a timing path comprising a plurality of a plurality of circuit elements, wherein the timing path exhibits a similar propagation delay as a corresponding a functional path of the integrated circuit;
clock counter circuitry coupled to the timing path, the clock counter circuitry configured to count output pulses of the timing path to determine a frequency associated with the timing path; and
pre-alarm circuitry coupled to the clock counter circuitry, the pre-alarm circuitry configured to generate a pre-alarm signal when the frequency associated with the timing path falls outside of a pass/fail boundary.

20. The checker logic circuitry of claim 19, wherein the timing path comprises a ring oscillator.
